(19) United States
(12) Patent Application Publication
(10) Pub. No.: US 2011/0277680 A1
(43) Pub. Date: Nov. 17, 2011

(54) ARTIFICIAL CORUNDUM CRYSTAL

(75) Inventors: Katsuya TESHIMA, Tokyo-to (JP); Shuji OISHI, Nagano (JP)

(73) Assignee: DAI NIPPON PRINTING CO., LTD., Tokyo-to (JP)

(21) Appl. No.: 13/190,792

(22) Filed: Jul. 26, 2011

Related U.S. Application Data
(62) Division of application No. 10/581,182, filed on Jun. 1, 2006.

(30) Foreign Application Priority Data
Dec. 1, 2003 (JP) 2003-402115
Feb. 5, 2004 (JP) 2004-029059
May 13, 2004 (JP) 2004-144118
May 13, 2004 (JP) 2004-144124
May 13, 2004 (JP) 2004-144125

(51) Int. Cl. C30B 9/02

(52) U.S. Cl. 117/79

(57) ABSTRACT

An artificial corundum crystal which can be put into practical use at low costs, and a process for producing the same. The artificial corundum crystal has at least one crystal face selected from {113}, {012}, {014}, {113}, {110}, {101}, {116}, {211}, {122}, {214}, {100}, {125}, {223}, {131}, and {312} faces. The process for producing the artificial corundum crystal is by a flux evaporation method of heating a sample containing a raw material and a flux to precipitate a crystal and grow the crystal by use of flux evaporation as a driving force.

### TECHNICAL FIELD

The present invention relates to an artificial corundum crystal which can be used as, for example, a laser-oscillating material, a highly hard bearing material, a standard material for physical property measurement, an ornament, a high-value added article for daily use, and the like.

### BACKGROUND ART

In recent years, such monocrystals as are naturally present, which have a three-dimensional shape peculiar to the crystals, have been desired in various fields because of unknown properties thereof.

Examples of a method for producing an artificial corundum crystal include (1) the flame fusion method (Verneuil's technique) of dropping raw material powder of the corundum crystal into oxygen and hydrogen flame and simultaneously growing crystal grains; (2) the flux method of mixing raw material powder of the corundum crystal with an appropriate flux, melting the mixture in a crucible, and precipitating/growing the crystal while cooling the melted solution slowly or precipitating/growing the crystal while applying temperature gradient to the solution in the crucible, or precipitating/growing the crystal while vaporizing the flux; (3) the Czochralski method of melting raw material powder of the corundum crystal in a crucible, and pulling up the crystal from melt; and (4) a method of forming raw material powder of the corundum crystal into a shape, and then heating the shaped powder at a high temperature in a hydrogen gas atmosphere for a long time so as to sinter the powder.

In the flame fusion method (1), the growth rate of the crystal is large, so that the obtained crystal cannot be made into a high quality at ease. According to this method, a rodlike crystal is produced. Thus, at the time of actually using the crystal as a laser-oscillating material or the like, it is necessary to cut the produced rodlike crystal into a desired shape, and further the hardness of any artificial corundum crystal is high; accordingly, a problem that costs increase arises. Although the artificial corundum crystal produced by this method contains no purities, natural corundum crystal contains impurities. Thus, they can easily be distinguished from each other. Consequently, the artificial corundum crystal has a drawback that it is very low in value as an ornament.

The Czochralski method (3) makes it possible to produce a crystal having a high purity. Accordingly, the crystal can be preferably used as a laser-oscillating material or the like. However, according to this method, a rodlike crystal is produced. Thus, at the time of putting the crystal into practical use, it is necessary to cut the rodlike crystal into a desired shape as described above, and further the hardness of any artificial corundum crystal is high; accordingly, a problem that costs increase arises. Furthermore, the artificial corundum crystal produced by this method has a high purity not to contain any impurity, and is largely different from natural corundum crystal. Thus, the artificial corundum crystal has a drawback that the crystal is very low in value as an ornament. The Czochralski method is disclosed in, for example, the patent documents 1 and 2.

According to the method (4) of shaping followed by sintering, it is unavoidable to heat powder at high temperature for a long time. Thus, a large quantity of energy is needed, so as to cause a problem that costs increase. The method for the sintering is disclosed in, for example, the patent document 3.

It is known that according to the flux method (2), a tabular crystal can be obtained by using, as a flux, lithium oxide-lead oxide (fluoride), aluminum fluoride/sodium, lithium oxide-tungsten oxide-lead oxide (fluoride), bismuth oxide-lanthanum oxide-lead oxide (fluoride) or the like, and precipitating/growing a crystal while cooling the melted solution slowly. However, only a thin tabular crystal can be obtained. Thus, there arises a problem that costs increase when the crystal is put into practical use. The flux method is disclosed in, for example, the nonpatent literatures 1 and 2.
Patent document 1: Japanese Patent Application Laid-Open (JP-A) No. 7-277893
Patent document 2: JP-A No. 6-199597
Patent document 3: JP-A No. 7-187760
Nonpatent literature 1: Elwell D., Man-made gemstones, Ellis Horwood Ltd., Chichester (1979)
Nonpatent literature 2: Elwell D., Scheel H. J., Crystal growth from high-temperature solutions, Academic Press, London (1975)

### DISCLOSURE OF THE INVENTION

### Problem to be Solved by the Invention

The present invention has been made in light of the above-mentioned problems, and a main object thereof is to provide an artificial corundum crystal which can be put into practical use at low costs and a process for producing the same.

### Means for Solving the Problems

In order to attain the above-mentioned object, the present invention provides an artificial corundum crystal having at least one crystal face selected from the group consisting of {113}, {012}, {104}, {110}, {101}, {116}, {211}, {122}, {214}, {100}, {125}, {223}, {131}, and {312} faces.

The artificial corundum crystal has the above-mentioned crystal face(s) according to the invention. Thus, when the crystal is used as a laser-oscillating material or the like, it is unnecessary to apply cutting or any other processing to the crystal. Alternatively, even when cutting or any other processing is applied thereto, the processing can be carried out by use of the crystal face(s) that the artificial corundum crystal of the invention has; therefore, the crystal has an advantage that the crystal can be put into practical use at low costs. The artificial corundum crystal of the invention has an advantage that the crystal is high in value as an ornament or the like since the crystal has a polyhedral crystal and is near natural corundum crystal.

The invention also provides an artificial corundum crystal having a dominant crystal face other than a {001} face.

According to the invention, since the artificial corundum crystal has a dominant crystal face other than a {001} face, the crystal is not a crystal originating from a conventional tabular crystal whose {001} face is a dominant face. Thus, when the crystal is used as a laser-oscillating material or the like, cutting or any other processing is not applied thereto. Alternatively, even when cutting or any other processing is applied thereto, the processing can be carried out by use of the shape of the artificial corundum crystal of the invention. Accordingly, the crystal can be put into practical use at low costs. Additionally, the artificial corundum crystal of the invention has an advantage that the crystal is high in value as an ornament or the like since the crystal is near natural corundum crystal.

It is preferred that the artificial corundum crystal of the invention is derived from a crystal having a hexagonally dipyramidal shape. This makes it possible to obtain an artificial corundum crystal having the given crystal face(s). Thus, when the crystal is used as a laser-oscillating material or the like, processing can be applied thereto in the state that the hexagonally dipyramidal shape is used. Consequently, the crystal can be put into practical use at low costs. Since the crystal originates from the hexagonally dipyramidal crystal, the crystal is a polyhedral crystal and is near natural corundum crystal. For this reason, the value thereof as an ornament or the like becomes high.

In the invention, the artificial corundum crystal may be colorless. Alternatively, it is allowable to add, into the artificial corundum crystal, a chromium, an iron and a titanium, a nickel, a vanadium or a cobalt as a coloring component or coloring components.

The invention also provides a process for producing an artificial corundum crystal, in which an artificial corundum crystal having a hexagonally dipyramidal shape as its base shape is produced by a flux evaporation method of heating a sample containing a raw material and a flux to precipitate a crystal and grow the crystal by use of flux evaporation as a driving force.

According to the invention, the use of the flux evaporation method makes it possible to produce an artificial corundum crystal having a hexagonally dipyramidal shape as its base shape. Thus, when the crystal is used as a laser-oscillating material or the like, cutting or any other processing is not applied thereto. Alternatively, even when cutting or any other processing is applied thereto, the processing can be carried out by use of the hexagonally dipyramidal shape. Accordingly, an artificial corundum crystal capable of being put into practical use at low costs can be produced. According to the flux evaporation, since a crystal near natural corundum crystal is obtained, the value thereof as an ornament or the like can be made high. Furthermore, an apparatus used in the flux evaporation method is simply composed of a high-temperature furnace and a crucible. Thus, a hexagonally dipyramidal artificial corundum crystal can easily be produced.

It is also preferred in the invention that the flux contains a molybdenum compound. The molybdenum compound is preferably a molybdenum oxide or a compound which is heated to generate the molybdenum oxide. The use of the molybdenum compound as the flux makes it possible not to produce any tabular or needle crystal but to produce a hexagonally dipyramidal crystal selectively.

In the invention, the flux may contain an evaporation inhibitor. This makes it possible to inhibit the evaporation speed of the flux so as to inhibit the generation of polynuclei and the speed of crystal growth. Consequently, a high-quality artificial corundum crystal can be produced.

It is also preferred in the invention that the evaporation inhibitor is an alkali metal compound. The alkali metal compound is preferably an alkali metal oxide, or a compound which is heated to generate the alkali metal oxide. The alkali metal compound is in particular preferably a compound which is heated to generate at least one kind of alkali metal oxide selected from the group consisting of Li₂O, Na₂O₁ and K₂O. The use thereof makes it possible to restrain the evaporation of the flux effectively, so as to produce a high-quality and large-sized artificial corundum crystal.

It is also preferred in the invention that the mol number of the alkali metal atom(s) in the alkali metal compound(s) is 40% or less by mol of the total mol numbers of the sample. In the invention, the formation of nuclei and crystal growth are promoted by use of evaporation of the flux as a driving force; therefore, if the content of the alkali metal compound is larger than the above-mentioned range, the crystallization may be disturbed.

It is also preferred in the invention that the mol number of the raw material is 10% or less by mol of the total mol numbers of the sample. If the content of the raw material is larger than the above-mentioned range, the raw material is not melted into the flux at ease so that the crystallization may be disturbed.

The invention also provides a raw material for producing an artificial corundum crystal, which is used to produce an artificial corundum crystal and contains a molybdenum compound and an aluminum compound.

When the raw material for producing an artificial corundum crystal of the invention is used to produce an artificial corundum crystal, the produced artificial corundum crystal can be made not into a tabular or needle form but into a hexagonally dipyramidal form selectively. As described above, accordingly, the crystal can be put into practical use at low costs, and further a crystal high in value as an ornament or the like can be obtained.

In the invention, the raw material for producing an artificial corundum crystal may contain an alkali metal compound. The alkali metal compound restrains the molybdenum compound or the like from evaporating; therefore, when the raw material for producing an artificial corundum crystal of the invention is used to produce an artificial corundum crystal, the generation of polynuclei and the speed of crystal growth can be restrained to make it possible to obtain a high-quality artificial corundum crystal.

It is also preferred in the invention that the molybdenum compound is a molybdenum oxide, or a compound which is heated to generate the molybdenum oxide.

It is also preferred in the invention that the aluminum compound is an aluminum oxide, or a compound which is heated to generate the aluminum oxide.

It is also preferred in the invention that the alkali metal compound is an alkali metal oxide, or a compound which is heated to generate an alkali metal oxide. These make it possible to inhibit the evaporation of the flux effectively. Accordingly, when the raw material for producing an artificial corundum crystal of the invention is used to produce an artificial corundum crystal, the obtained crystal can be a high-quality and large-sized artificial corundum crystal.

It is allowable in the invention that the raw material for producing an artificial corundum crystal contains: a chromium compound which is heated to generate a chromium ion; an iron compound which is heated to generate an iron ion and a titanium compound which is heated to generate a titanium ion; a nickel compound which is heated to generate a nickel ion; a vanadium compound which is heated to generate a vanadium ion; or a cobalt compound which is heated to generate a cobalt ion.

### Effect of the Invention

According to the invention, an artificial corundum crystal having a hexagonally dipyramidal shape as its base shape can be produced by using the flux evaporation method; therefore, when the crystal is used as a laser-oscillating material or the like, the crystal is easily processed or worked and can be put into practical use at low costs. Additionally, the invention has an advantage that the crystal is high in value as an ornament or the like since a crystal near natural corundum crystal is obtained.

### BRIEF DESCRIPTION OF DRAWINGS

FIGS. 1A and 1B are forms each showing an example of an artificial corundum crystal of the invention.

FIGS. 2A to 2C are graphs showing an example of the X-ray diffraction pattern of the artificial corundum crystal of the invention.

FIGS. 3A to 3C are graphs showing another example of the X-ray diffraction pattern of the artificial corundum crystal of the invention.

FIGS. 4A and 4B are each optical microscope photograph showing an example of the artificial corundum crystal of the invention.

FIGS. 5A to 5D are process charts showing an example of the process of the invention for producing an artificial corundum crystal.

### EXPLANATION OF REFERENCES

1 . . . sample
1′ . . . remaining sample
2 . . . artificial corundum crystal
11 . . . mortar
12 . . . crucible
13 . . . high-temperature furnace

### BEST MODE FOR CARRYING OUT THE INVENTION

The present invention includes an artificial corundum crystal, a process for producing the same, and a raw material for producing an artificial corundum crystal. The following describes each of them in detail.

A. Artificial Corundum Crystal

First, the artificial corundum crystal of the invention is described.

The artificial corundum crystal of the invention can be classified into two embodiments. The first embodiment is an artificial corundum crystal having at least one crystal face selected from the group consisting of {113}, {012}, {104}, {110}, {101}, {116}, {211}, {122}, {214}, {100}, {125}, {223}, {131}, and {312} faces. The second embodiment is an artificial corundum crystal having a dominant face other than a {001} face.

The following describes each of the embodiments.

### 1. First Embodiment

The first embodiment of the artificial corundum crystal of the invention is an artificial corundum crystal having at least one crystal face selected from the group consisting of {113}, {012}, {104}, {110}, {101}, {116}, {211}, {122}, {214}, {100}, {125}, {223}, {131}, and {312} faces.

Corundum crystal is described herein. Corundum crystal has a corundum structure belonging to the trigonal system. This corundum structure has the following structure: cations (Al) regularly occupy ⅔ of hexacoordinate (octahedron) positions of a substantially hexagonal-closest-packed lattice; and AlO₆ octahedrons, the center of each of which is a cation (Al), partially have faces in common, and are jointed to each other in a “z” axis direction. In general, the crystal is converted to chromium-added corundum crystal by substituting Cr partially for Al of corundum (Al₂O₃).

Corundum (Al₂O₃) is the most stable in alumina polymorphs. Corundum crystal having such a corundum structure has a melting point of about 2050° C., has a high hardness (Mohs hardness: 9), and is excellent in chemical resistance, abrasion resistance, and weather resistance. In a high-temperature environment also, the crystal exhibits a high electrical insulation property. Since corundum crystal has the above-mentioned nature, the crystal is used in a bearing for meters, a micro-scalpel, an optical switch element, a laser-oscillating material, and so on. Corundum crystal is converted to a crystal having a different hue by substituting Cr, Ti, Fe, or the like partially for Al of corundum (Al₂O₃). The resultant crystal is generally called ruby or sapphire, and is used as an ornament.

As the process for producing an artificial corundum crystal, the Czochralski method, the flame fusion method, the flux method, the sintering method, and so on are known up to the present time. The artificial corundum crystal created by the Czochralski method or the flame fusion method is yielded as a rodlike crystal. Thus, the crystal does not have a complicated shape. The artificial corundum crystal created by the sintering method is sintered after the crystal is shaped. Therefore, in this case also, the crystal does not have a complicated shape. On the other hand, according to the flux slow-cooling method, a tabular crystal is obtained, and thus the obtained artificial corundum crystal has crystal faces. However, the dominant face thereof is a {001} face.

As described above, artificial corundum crystals have been hitherto obtained as rodlike or tabular crystals. It is therefore necessary to apply cutting or some other processing thereto so as to make the crystal into a desired shape at the time of using the crystal as a laser-oscillating material or the like. As described above, artificial corundum crystals have high hardness. Consequently, an inconvenience that costs increase is caused. The artificial corundum crystal produced by the Czochralski method or the flame fusion method contains no impurities while natural corundum crystal contains impurities, and thus these can easily be distinguished from each other. Accordingly, the artificial corundum crystal is low in value as an ornament or the like.

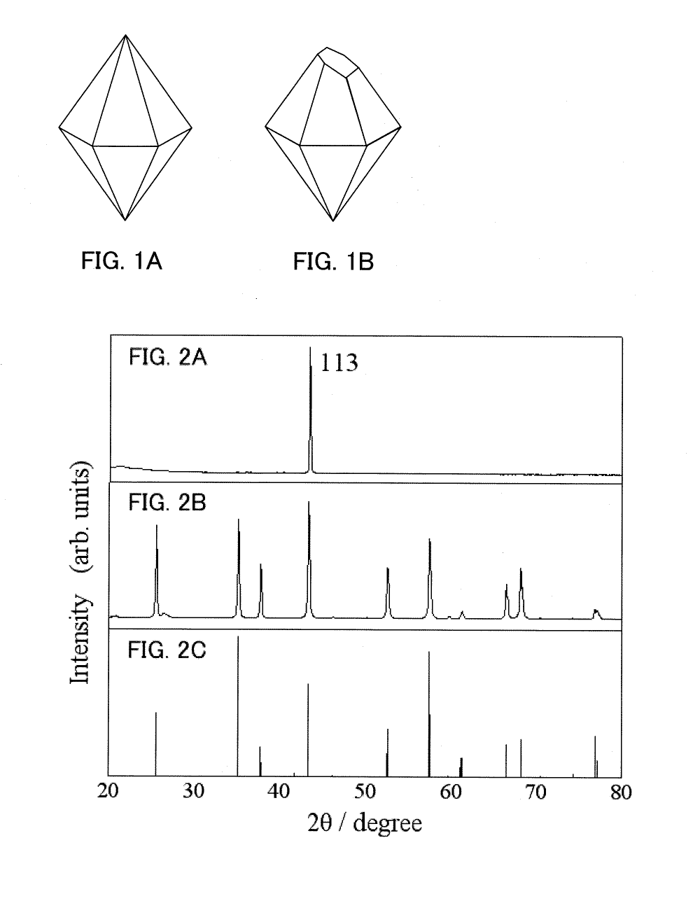

The artificial corundum crystal in the present embodiment has given crystal face (s), and the crystal face (s) originate (s) from the hexagonally dipyramidal crystal. The hexagonally dipyramidal crystal means, for example, an artificial corundum crystal having a shape as shown in FIG. 1A. The artificial corundum crystal originates from the hexagonally dipyramidal crystal in the present embodiment; therefore, at the time of using the crystal as a laser-oscillating material, an ornament or the like, cutting or any other processing is not applied thereto. Alternatively, even if cutting or any other processing is applied thereto, the embodiment has an advantage that the crystal can be put into practical use at low costs since the processing can be performed by use of the crystal face (s) which the artificial corundum crystal of the invention has.

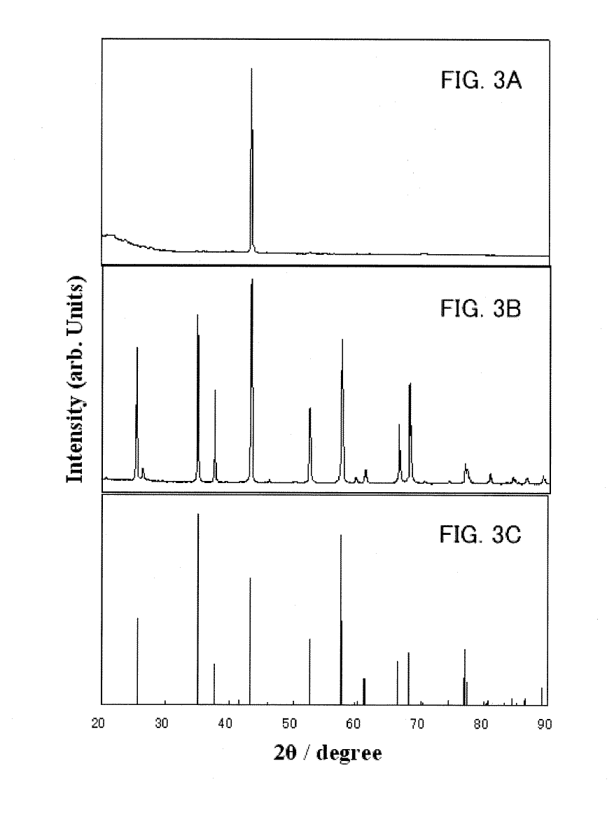

The above-mentioned crystal and crystal faces are each identified or measured by use of an X-ray diffractometer. At this time, in the trigonal system, “a” and “c” are set to 4.759 Å and 12.991 Å, respectively, and obtained data are compared with JCPDS No. 46-1212 in the identification. Examples of the X-ray diffraction pattern of crystal faces of the artificial corundum crystal of the present embodiment are shown in FIG. 2A and FIG. 3A. FIG. 2B and FIG. 3B are X-ray diffraction patterns measured by pulverizing the artificial corundum crystal of the embodiment in order to identify the crystal. In the embodiment, in order for the artificial corundum crystal to have the given crystal face (s), it is sufficient that for example a peak assigned to any one of the given crystal faces is detected as shown in FIG. 2A and FIG. 3A. FIGS. 2C and 3C are X-ray diffraction patterns of JCPDS No. 46-1212, and the X-ray diffraction patterns of FIGS. 2A-2C and FIGS. 3A-3C were measured using a CuKα ray.

In the invention, for example, a {101} face means all faces equivalent to a (101) face, that is, a (101) face and a (011) face, or multiples thereof, such as a (202) face, a (022) face, a (303) face, a (033) face, a (404) face, a (044) face, and other faces. The same matter is applied to the other given crystal faces.

The artificial corundum crystal of the embodiment has the given crystal face(s), thereby being distinguished from the artificial corundum crystal produced by any conventional production process. For example, the artificial corundum crystal produced by the Czochralski method does not have a complicated crystal shape and it is substantially impossible to work the crystal to have a specified crystal face even if cutting or any other processing is applied thereto. The artificial corundum crystal produced by the flux slow-cooling method is a tabular crystal, and has a {001} face as its dominant crystal face. However, it is usually impossible to work the crystal to have a crystal face originating from a hexagonally dipyramidal crystal as described above.

It is sufficient in the embodiment that the artificial corundum crystal originates from a hexagonally dipyramidal crystal. The artificial corundum crystal may have a crystal face other than the above-mentioned crystal faces.

The wording “originates from a hexagonally dipyramidal crystal” means that the artificial corundum crystal of the embodiment may be an artificial corundum crystal having a hexagonally dipyramidal shape as its basic shape or may be a crystal obtained by applying cutting or some other processing to a hexagonally dipyramidal artificial corundum crystal.

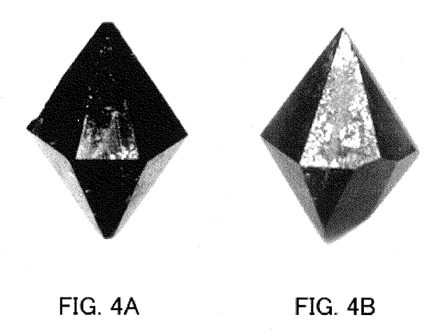

The wording “having a hexagonally dipyramidal shape as its basic shape” means a hexagonally dipyramidal artificial corundum crystal as shown in, for example, FIG. 1A or 4A, or an artificial corundum crystal in which one or more parts of a hexagonal dipyramid are chipped so that one or more different crystal faces make its/their appearance. FIGS. 4A and 4B are optical microscope photographs obtained by photographing chromium-added artificial corundum crystals, using an optical microscope (VH-Z450+VH-7000, manufactured by KEYENCE CORPORATION.).

The artificial corundum crystal of the embodiment may be colorless, or may be colored by adding, to an artificial corundum crystal, an additive such as chromium, iron, titanium, nickel, vanadium or cobalt.

It is known that a corundum crystal turns to a crystal having a different hue in accordance with the kind of the additive such as chromium, iron, titanium, nickel, vanadium or cobalt. For example, the crystal to which no additive is added is colorless; the crystal to which chromium is added is dark red, red or pink; the crystal to which titanium and iron are added is blue; the crystal to which nickel is added is yellow; the crystal to which vanadium is added is alexandrite; the crystal to which nickel and chromium, or nickel, chromium and iron are added is orange; the crystal to which nickel, titanium and iron are added is yellowish green; and the crystal to which titanium, chromium, and iron are added is purple. Any corundum crystal other than the dark red corundum crystal, to which chromium is added, is generally called sapphire.

About the artificial corundum crystal of the embodiment, it is preferred to add a chromium; an iron and a titanium; a nickel; a vanadium; or a cobalt as one or more coloring Components to the crystal, whereby the crystal is colored into the following color: dark red; red or pink; blue; yellow; alexandrite; or green, respectively. In other words, it is preferred that the artificial corundum crystal of the embodiment is a dark red, red or pink artificial corundum crystal (chromium-added artificial corundum crystal); a blue artificial corundum crystal; a yellow artificial corundum crystal; an alexandrite artificial corundum crystal; or a green artificial corundum crystal.

The wording “colored into alexandrite” means that an artificial corundum crystal has color-changeability. The wording “an alexandrite artificial corundum crystal” means an artificial corundum crystal having color-changeability. The range in which the color-changeability is exhibited is not particularly limited. For example, the crystal is changed as follows: dark bluish green or dark yellowish green is exhibited under light having an intense bluish green spectrum (for example, sunlight or fluorescent light); and dark reddish purple or dark reddish brown is exhibited under light having an intense red spectrum (for example, candle light or incandescent light).

In the embodiment, it is allowable about the yellow artificial corundum crystal to add iron, together with nickel, as a coloring component. In this case, examples of the combination of the coloring components include nickel only; and a combination of nickel and iron.

It is allowable about the alexandrite artificial corundum crystal to add at least one element selected from iron, titanium, and chromium, together with vanadium, as one or more coloring components. In this case, examples of the combination of the coloring components include vanadium only; vanadium and iron; vanadium and titanium; vanadium and chromium; vanadium, iron and titanium; vanadium, iron and chromium; vanadium, titanium, and chromium; vanadium, iron, titanium, and chromium.

It is allowable about the green artificial corundum crystal to add at least one element selected from iron, vanadium and nickel together with cobalt, as one or more coloring components. In this case, examples of the combination of the coloring components include cobalt only; cobalt and iron; cobalt and vanadium; cobalt and nickel; and cobalt, vanadium and nickel.

The artificial corundum crystal of the embodiment may contain a metal other than the above-mentioned chromium, iron, titanium, nickel, vanadium and cobalt, or a compound of the metal.

It can be identified with/by EPMA (electron probe microanalizer), XPS (X-ray photoelectron spectrometry) or EDX (energy dispersive X-ray analysis), that chromium, iron, titanium, nickel, vanadium, cobalt or the like is added.

The stoichiometric composition of the colorless artificial corundum crystal is represented by Al₂O₃. The stoichiometric composition of the dark red, red or pink artificial corundum crystal (chromium-added artificial corundum crystal) is represented by Al₂O₃:Cr. The stoichiometric composition of the blue artificial corundum crystal is represented by Al₂O₃:Fe, Ti. The stoichiometric composition of the yellow artificial corundum crystal, which is varied by the combination of the above-mentioned coloring components, can be represented by, for example, Al₂O₃:Ni or Al₂O₃:Ni, Fe. The stoichiometric composition of the alexandrite artificial corundum crystal, which is varied by the combination of the above-mentioned coloring components, can be represented by, for example, Al₂O₃:V, Al₂O₃:V, Fe, Al₂O₃:V, Ti, Al₂O₃:V, Cr, Al₂O₃:V, Fe, Ti, Al₂O₃:V, Fe, Cr, Al₂O₃:V, Ti, Cr, or Al₂O₃:V, Fe, Ti, Cr. The stoichiometric composition of the green artificial corundum crystal, which is varied by the combination of the above-mentioned coloring components, can be represented by, for example, Al₂O₃:Co, Al₂O₃:Co, Fe, Al₂O₃:Co, V, Al₂O₃:Co, Ni, or Al₂O₃:Co, V, Ni.

In the embodiment, any one of the artificial corundum crystals is not limited to a crystal having a stoichiometric composition, and may be a crystal not having a stoichiometric composition. The artificial corundum crystal of the embodiment is preferably produced by the flux evaporation method, as will be described later, for the following reason: when the artificial corundum crystal is produced by the flux evaporation method, the crystal may contain, as an impurity, an element contained in the flux. The impurity content in the artificial corundum crystal is usually an extremely small amount which is 1% or less by mol.

The content of the coloring component (s) in the artificial corundum crystal is not particularly limited as long as the coloring component (s) making it possible to color the artificial corundum crystal is/are contained, and may be extremely small. For example, the Cr content in the dark red, red or pink artificial corundum crystal (chromium-added artificial corundum crystal) is not particularly limited as long as Cr is contained to the extent that it can color the crystal into the dark red, red or pink artificial corundum crystal, and may be extremely small. The iron and titanium content in the blue artificial corundum crystal is not particularly limited as long as iron and titanium are contained to the extent that they can color the crystal into the blue artificial corundum crystal, and may be extremely small. The content of the coloring component (s) such as nickel in the yellow artificial corundum crystal is not particularly limited as long as the coloring component(s) is(are) contained to the extent that it(they) can color the crystal into the yellow artificial corundum crystal, and may be extremely small. The content of the coloring component(s) such as vanadium in the alexandrite artificial corundum crystal is not particularly limited as long as the coloring component(s) is(are) contained to the extent that it(they) can color the crystal into the alexandrite artificial corundum crystal, and may be extremely small. The content of the coloring component (s) such as cobalt in the green artificial corundum crystal is not particularly limited as long as the coloring component(s) is(are) contained to the extent that it (they) can color the crystal into the green artificial corundum crystal, and may be extremely small.

In the embodiment, the artificial corundum crystal is preferably produced by the flux evaporation method for the following reasons: the apparatus used in the flux evaporation method is simply composed of a high-temperature furnace and a crucible, and thus a hexagonally dipyramidal artificial corundum crystal can easily be provided; in accordance with the kind of the used flux, it is possible not to produce a tabular crystal or needle crystal but to produce a hexagonally dipyramidal crystal selectively; and the artificial corundum crystal produced by the flux evaporation method may contain, as an impurity, an element contained in the flux as described above, and thus a crystal containing the impurity can be produced in the same manner as in the case of natural corundum, whereby the artificial corundum crystal has an advantage that the crystal is high in value as an ornament or the like since the crystal is near natural crystal.

The process for producing the artificial corundum crystal, such as the flux evaporation method, will be described later in the column “B. A process for producing an artificial corundum crystal”. Thus, description thereof is not repeated herein.

The artificial corundum crystal of the embodiment may be a crystal into which an impurity is intentionally incorporated. As described above, the incorporation of the impurity gives an advantage that the crystal can be made near to natural crystal and is high in value as an ornament or the like.

### 2. Second Embodiment

The second embodiment of the artificial corundum crystal of the invention is an artificial corundum crystal having a dominant crystal face other than a {001} face.

As described about the first embodiment, the artificial corundum crystal produced by the Czochralski method, the flame fusion method or the sintering method in the prior art does not have any complicated crystal shape. Since the flux slow-cooling method gives a tabular crystal, the artificial corundum crystal has crystal faces; however, the dominant crystal face thereof is a {001} face.

The artificial corundum crystal of the present embodiment is an artificial corundum crystal having a dominant crystal face other than a {001} face. Such a crystal face does not originate from any tabular crystal, but originates from a hexagonally dipyramidal crystal in the same manner as in the first embodiment. Since the artificial corundum crystal in the embodiment has a dominant crystal face other than a {001} face and originates from a hexagonally dipyramidal crystal, cutting or any other processing is not applied thereto when the crystal is used as a laser-oscillating material, ornament or the like. Alternatively, even if cutting or any other processing is applied thereto, the embodiment has an advantage that the processing can be performed by use of the crystal face (s) which the artificial corundum crystal of the invention has, so that the crystal can be put into practical use at low costs.

The wording “having a dominant crystal face other than a {001} face” means the matter of having no {001} face, or the following: when a crystal has a {001} face, a peak is present which has a larger intensity than the peak assigned to the {001} face in the X-ray diffraction pattern thereof. The dominant crystal face other than a {001} face is preferably any one of the given crystal faces described about the first embodiment.

The other matters of the artificial corundum crystal are the same as described about the first embodiment. Thus, description thereof is not repeated herein.

B. A Process for Producing an Artificial Corundum Crystal

Next, the following describes the process for producing an artificial corundum crystal of the invention.

The process for producing an artificial corundum crystal of the invention is characterized in that an artificial corundum crystal having a hexagonally dipyramidal shape as its base shape is produced by a flux evaporation method of heating a sample containing a raw material and a flux to precipitate a crystal and grow the crystal by use of flux evaporation as a driving force.

The flux method is one of the solution methods, and is also called the fusing agent method. When a crystal is grown by the flux method, a salt or oxide which becomes the flux is mixed with a raw material which becomes a solute and then the mixture is heated and melted. Thereafter, the solution is turned into a supersaturated state while the solution is slowly cooled or the flux is vaporized. In this way, a crystal is grown. In accordance with difference in the method for producing this supersaturated state, the flux method is roughly classified into the flux evaporation method, the flux slow-cooling method, and the flux temperature gradient method.

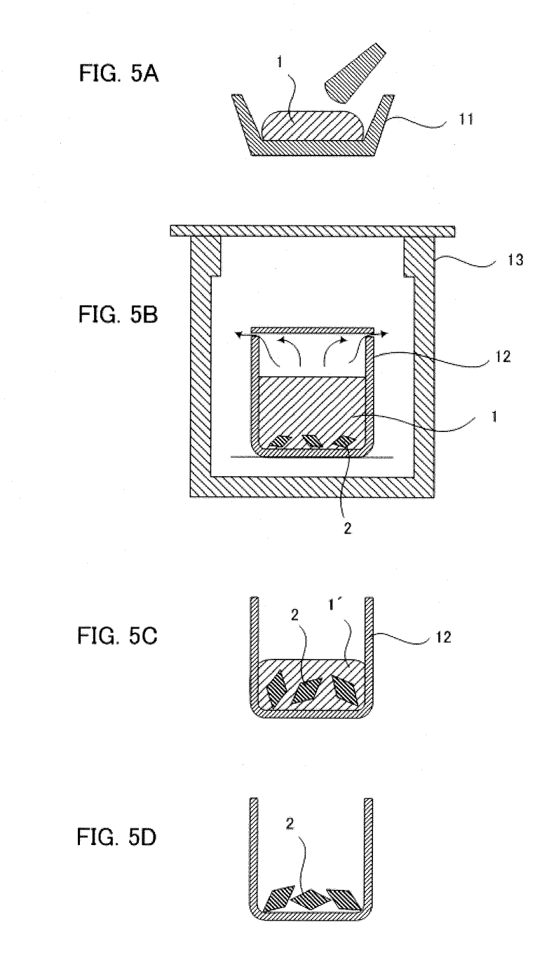

In the invention, the flux evaporation method out of the above is used. The flux evaporation method is a method of promoting the formation of nuclei and crystal-growth by use of the evaporation of a flux as a driving force. For example, as shown in FIG. 5B, a crucible 12 filled with a sample 1 containing a flux and a raw material is set in a high-temperature furnace 13, and then heated to vaporize the flux in the sample 1, thereby precipitating and growing an artificial corundum crystal 2. In this way, a sample 1′ containing the artificial corundum crystal 2 is obtained, as shown in FIG. 5C. This remaining sample 1′ is dissolved into an appropriate medium, whereby the artificial corundum crystal 2 can be separated.

The following is known as the process for producing an artificial corundum crystal using the flux method: by the flux slow-cooling method, in which a solution is turned into a supersaturated state while the solution is slowly cooled, a crystal is grown and a tabular crystal can be obtained, using a lead-based flux such as lithium oxide-lead oxide (fluoride), lithium oxide-tungsten oxide-lead oxide (fluoride), or bismuth oxide-lanthanum oxide-lead oxide (fluoride). However, the crystal obtained by this method is only a thin tabular crystal. Thus, a large-sized crystal having a high quality is not easily produced. It is therefore necessary to cut the tabular crystal into a desired shape when the crystal is used as a laser-oscillating material or the like. Furthermore, an inconvenient that costs increase is caused since the artificial corundum crystal has a high hardness.

Although the flux method has such a problem, an element contained in a flux may be contained as an impurity in the crystal according to the flux method. The resultant artificial corundum crystal contains the impurity, and can be made near to natural corundum crystal; thus, the flux method, which is different from the Czochralski method and so on, has an advantage that the resultant crystal is high in value as an ornament or the like.

In the invention, the flux evaporation method is used, whereby an artificial corundum crystal having a hexagonally dipyramidal shape as its basic shape can be produced, as shown in, for example, FIG. 1A or 4A. It is accordingly possible to provide, at low costs, a high value added artificial corundum crystal which is easily processed when the crystal is put into practical use. It is sufficient that the apparatus used in the flux evaporation method has a high-temperature furnace 13 and a crucible 12 as shown in FIG. 5B. Thus, the apparatus is simple. In the flux evaporation method, an artificial corundum crystal is obtained by vaporizing a flux to precipitate and grow a crystal, and then dissolving the remaining sample into an appropriate medium. Consequently, the production process therefor is simple. As described above, an artificial corundum crystal may contain, as an impurity, an element contained in the flux according to the flux evaporation method, and thus a crystal near natural corundum crystal is obtained. Therefore, an artificial corundum crystal high in value as an ornament or the like can be produced.

In the invention, the artificial corundum crystal having a hexagonally dipyramidal shape as its basic shape may be not only a hexagonally dipyramidal crystal as shown in FIG. 1A or 4A, but also a crystal in which one or some parts of a hexagonally dipyramidal shape are chipped so that one or more different crystal faces make its/their appearance as shown in FIG. 1B or 4B.

FIGS. 5A to 5D are process charts showing an example of the process for producing an artificial corundum crystal of the invention. As shown in FIGS. 5 A to 5D, the process for producing an artificial corundum crystal of the invention comprises a sample-preparing step of stirring a flux and a raw material in a mortar 11 to prepare a sample 1 (FIG. 5A); a heating/vaporizing step of setting a crucible 12 filled with the sample 1 into a high-temperature furnace 13, heating the sample, and further keeping the sample at high temperature to vaporize the flux (FIG. 5B); a cooling step of cooling the sample fused in the heating/vaporizing step (FIG. 5C); and a separating step (crystal-collecting step) of dissolving a sample 1′ remaining after the heating/vaporizing step and the cooling step into an appropriate medium so as to separate an artificial corundum crystal 2 (FIG. 5D).

The following describes each of the steps of such a process for producing an artificial corundum crystal.

1. Sample-Preparing Step

In the process for producing an artificial corundum crystal of the invention, the sample-preparing step is performed first, in which a flux and a raw material are stirred to prepare a sample.

In the present step, the method for stirring the flux and the raw material is not particularly limited as long as the method is a method making it possible to stir them into a homogeneous form. For example, a method of stirring the flux and the raw material in a mortar can be used.

The sample used in the invention is a sample containing a flux and a raw material. The following describes the flux and the raw material separately.

(1) Flux

The flux used in the invention is not particularly limited if the flux is a substance which evaporates in the heating/vaporizing step which will be described later, and which is dissolved in an appropriate medium in the separating step which will be also described later. The flux preferably contains a molybdenum compound. When the flux contains the molybdenum oxide, it is possible not to produce a tabular or needle artificial corundum crystal but to produce selectively an artificial corundum crystal having a hexagonally dipyramidal shape as its basic shape.

As such a molybdenum compound, there can be used the molybdenum oxide, or a compound which is heated in the heating/vaporizing step, which will be described later, to generate the molybdenum oxide. Examples of the compound, which is heated to generate the molybdenum oxide, include a molybdenum carbonate, a molybdenum sulfate, a molybdenum nitrate, a molybdenum hydroxide, and hydrates thereof. Of these, the molybdenum oxide is preferably used in the invention.

In the invention, the flux may contain an evaporation inhibitor. This makes it possible to inhibit the evaporation speed of the flux to suppress the generation of polynuclei and the speed of crystal growth, whereby a high-quality artificial corundum crystal can be produced.

On the other hand, when the flux does not contain the evaporation inhibitor, the speed of nuclei formation is large so that a large number of nuclei are formed. Consequently, a great number of artificial corundum crystals can be produced.

The evaporation inhibitor is not particularly limited if the inhibitor is a substance which can inhibit the evaporation of the flux and is dissolved in an appropriate medium in the separating step, which will be described later. In the invention, it is preferred to use an alkali metal compound. The use of the alkali metal compound makes it possible to inhibit the evaporation of the flux effectively and produce a high-quality and large-sized artificial corundum crystal.

As such an alkali metal compound, there can be used an alkali metal oxide or a compound which is heated in the heating/vaporizing step, which will be described later, to generate the alkali metal oxide. Examples of the compound, which is heated to generate the alkali metal oxide, include alkali metal carbonates, alkali metal sulfates, alkali metal nitrates, alkali metal hydroxides, and hydrates thereof. In the invention, preferred is at least one kind of alkali metal oxide selected from the group consisting of Li₂O, Na₂O and K₂O among the above.

About the content of the alkali metal compound, the mol number of the alkali metal atom in the alkali metal compound is preferably 40% or less by mol of the total mol numbers of the sample; more preferably 30% or less by mol thereof; and in particular preferably 20% or less by mol thereof. In the invention, the formation of nuclei and crystal growth are promoted by use of the evaporation of the flux as a driving force; therefore, if the content of the alkali metal compound is larger than the above-mentioned range, the crystallization may be hindered.

(2) Raw Material

The following describes the raw material used in the invention. In the invention, the raw material is a material for forming an artificial corundum crystal. As described in the above-mentioned column “A. Artificial corundum crystal”, artificial corundum crystals have different basic compositions corresponding to a colorless artificial corundum crystal, a dark red, red or pink artificial corundum crystal (chromium-added artificial corundum crystal), a blue artificial corundum crystal, a yellow artificial corundum crystal, an alexandrite artificial corundum crystal, and a green artificial corundum crystal. The following describes the colorless artificial corundum crystal, the dark red, red or pink artificial corundum crystal (chromium-added artificial corundum crystal), the blue artificial corundum crystal, the yellow artificial corundum crystal, the alexandrite artificial corundum crystal, and the green artificial corundum crystal separately.

(i) Colorless Artificial Corundum Crystal

Since the colorless artificial corundum crystal has a basic composition represented by Al₂O₃ in the invention, an aluminum compound (Al₂O₃ source) should be prepared as the raw material.

As the aluminum compound (Al₂O₃ source), there can be used an aluminum oxide, or a compound which is heated in the heating/vaporizing step, which will be described later, to generate the aluminum oxide. Examples of the compound, which is heated to generate the aluminum oxide, include an aluminum hydroxide, an aluminum sulfate, an aluminum carbonate, an aluminum nitrate, and hydrates thereof. Of these, the aluminum oxide is preferably used in the invention.

The composition of the colorless artificial corundum crystal is the same as described in the above-mentioned column “A. Artificial corundum crystal”. Thus, description thereof is not repeated herein.

About the content of the raw material in the invention, the mol number of the raw material is preferably 10% or less by mol of the total mol numbers of the sample. If the content of the raw material is larger than this range, the flux is not easily dissolved so that the crystallization may be hindered. Since the crystal is formed as long as the raw material is contained by only a small amount, the lower limit of the content of the raw material is not particularly limited.

(ii) Dark Red, Red or Pink Artificial Corundum Crystal (Chromium-Added Artificial Corundum Crystal)

Since the dark red, red or pink artificial corundum crystal (chromium-added artificial corundum crystal) has a basic composition represented by Al₂O₃:Cr in the invention, the raw material can be divided into an aluminum compound (Al₂O₃ source) and a chromium compound (Cr source).

The chromium compound (Cr source) is not particularly limited if the compound is a compound which is melted in the heating/vaporizing step, which will be described later. The compound is preferably a compound which is heated to generate a chromium ion. Examples of the compound, which is heated to generate a chromium ion, include a chromium oxide, a chromium hydroxide, a chromium sulfate, a chromium carbonate, a chromium nitrate, and hydrates thereof. Of these, the chromium oxide is preferably used in the invention.

The aluminum compound (Al₂O₃ source) is the same as described in the above-mentioned column of the colorless artificial corundum crystal. Thus, description thereof is not repeated herein.

About the mixing ratio between the aluminum compound (Al₂O₃ source) and the chromium compound (Cr source), they should be mixed at a stoichiometric ratio so as to give a predetermined composition. In the case of using, for example, an aluminum oxide and a chromium oxide as the raw material, the adding amount of the chromium oxide should be 5% or less by weight of the aluminum oxide weight. The amount is preferably 2% or less by weight thereof, and more preferably 1% or less by weight thereof.

The content of the raw material, and so on are the same as the above-mentioned column of the colorless artificial corundum crystal. The composition of the dark red, red or pink artificial corundum crystal (chromium-added artificial corundum crystal) is the same as described in the above-mentioned column “A. Artificial corundum crystal”. Thus, description thereof is not repeated herein.

(iii) Blue Artificial Corundum Crystal

Since the blue artificial corundum crystal has a basic composition represented by Al₂O₃:Fe, Ti in the invention, an aluminum compound, an iron compound and a titanium compound should be prepared as the raw material.

The iron compound is not particularly limited if the compound is a compound which is melted in the heating/vaporizing step, which will be described later. The compound is preferably a compound which is heated to generate an iron ion. Examples of the compound, which is heated to generate an iron ion, include an iron oxide, an iron hydroxide, an iron sulfate, an iron carbonate, an iron nitrate, an iron chloride, an iron citrate, an iron phosphate, an iron fluoride, an iron iodide, an iron oxalate, and hydrates thereof. Of these, the iron oxide is preferably used in the invention. In this case, the valence of iron in the iron oxide may be bivalent or trivalent. Bivalent iron and trivalent iron may be mixed.

The titanium compound is not particularly limited if the compound is a compound which is melted in the heating/vaporizing step, which will be described later. The compound is preferably a compound which is heated to generate a titanium ion. Examples of the compound, which is heated to generate a titanium ion, include a titanium oxide, a titanium nitride, a titanium tetraisopropoxide, a titanium oxalate, a titanium sulfide, a titanium bromide, a titanium chloride, and hydrates thereof. Of these, the titanium oxide is preferably used in the invention. In this case, the valence of a titanium in the titanium oxide includes bivalence, trivalence and quadrivalence. About the valence of the titanium, a single valence or mixed valences therefrom are permissible.

The aluminum compound is the same as described in the above-mentioned column of the colorless artificial corundum crystal. Thus, description thereof is not repeated herein.

The mixing ratio between the aluminum compound, the iron compound and the titanium compound is not particularly limited if the iron compound and the titanium compound are added in an amount which makes it possible to color the crystal into the blue artificial corundum crystal. In the case of using, for example, an aluminum oxide, an iron oxide and a titanium oxide as the raw material, the total adding amount of the iron oxide and the titanium oxide should be 5% or less by weight of the aluminum oxide weight; is preferably 2% or less by weight thereof; and is more preferably 1% or less by weight thereof. By setting the mixing ratio into the above-mentioned range, the blue artificial corundum crystal is colored into vivid blue color.

The mixing ratio between the iron compound and the titanium compound is varied by the valences of the iron and the titanium. Usually, the compounds are mixed to set the weight ratio between the iron element and the titanium element as follows: Fe:Ti=1:0.05-20. The compounds are preferably mixed to set the ratio to 1:0.07-15, in particular, 1:0.1-10. By setting the mixing ratio into the above-mentioned range, a blue artificial corundum crystal exhibiting vivid blue color can be obtained.

The content of the raw material is the same as described in the above-mentioned column of the colorless artificial corundum crystal, and the composition of the blue artificial corundum crystal is the same as described in the above-mentioned column “A. Artificial corundum crystal”. Thus, description thereof is not repeated herein.

(iv) Yellow Artificial Corundum Crystal

Since the yellow artificial corundum crystal has a basic composition represented by, for example, Al₂O₃:Ni in the invention, an aluminum compound and a nickel compound can be used as the raw material. In the invention, an iron as a coloring component may be added, together with a nickel, to the yellow artificial corundum crystal, as described in the column “A. Artificial corundum crystal”; therefore, as the raw material, a material in which an iron compound is added to an aluminum compound and a nickel compound may be used. In this case, examples of the combination of components of the raw material include the following combinations: an aluminum compound and a nickel compound; and an aluminum compound, a nickel compound and an iron compound.

The nickel compound is not particularly limited if the compound is a compound which is melted in the heating/vaporizing step, which will be described later. The compound is preferably a compound which is heated to generate a nickel ion. Examples of the compound, which is heated to generate a nickel ion, include a nickel acetate, a nickel carbonate, a nickel chloride, a nickel hydroxide, a nickel iodide, a nickel nitrate, a nickel oxide, a nickel sulfaminate, a nickel sulfate, and hydrates thereof. Of these, the nickel oxide is preferably used in the invention. In this case, the valence of the nickel in the nickel oxide may be bivalent or trivalent. Bivalent nickel and trivalent nickel may be mixed.

The aluminum compound is the same as described in the column of the colorless artificial corundum crystal, and the iron compound is the same as described in the column of the blue artificial corundum crystal. Thus, description thereof is not repeated herein.

The mixing ratio between the aluminum compound and the nickel compound is not particularly limited if the nickel compound is added in an amount making it possible to color the crystal into the yellow artificial corundum crystal. In the case of using the iron compound together with the aluminum compound and the nickel compound, the mixing ratio is not also particularly limited if the nickel compound and the iron compound, which become coloring components, are added in an amount making it possible to color the crystal into the yellow artificial corundum crystal.

In the case of using, for example, an aluminum oxide and a nickel oxide as the raw material, the adding amount of the nickel oxide should be 5% or less by weight of the aluminum oxide weight; is preferably 2% or less by weight thereof; is more preferably 1% or less by weight thereof. By setting the mixing ratio into the above-mentioned range, the yellow artificial corundum crystal is colored into vivid yellow color.

In the case of using, for example, the aluminum oxide, the nickel oxide and the iron oxide as the raw material, the total adding amount of the nickel oxide and the iron oxide should be 5% or less by weight of the aluminum oxide weight; is preferably 2% or less by weight thereof; and is more preferably 1% or less by weight thereof. By setting the mixing ratio into the above-mentioned range, the yellow artificial corundum crystal is colored into vivid yellow color, as described above. In such a case, the mixing ratio between the nickel oxide and the iron oxide is varied by the valences of a nickel and an iron, and should be appropriately selected in accordance with the usage of the yellow artificial corundum crystal produced by the invention.

The content of the raw material is the same as described in the column of the colorless artificial corundum crystal, and the composition of the yellow artificial corundum crystal is the same as described in the column of “A. Artificial corundum crystal”. Thus, description thereof is not repeated herein.

(v) Alexandrite Artificial Corundum Crystal

Since the alexandrite artificial corundum crystal has a basic composition represented by, for example, Al₂O₃:V in the invention, an aluminum compound and a vanadium compound can be used as the raw material. In the invention, an iron, a titanium, a chromium or the like as a coloring component may be added, together with a vanadium, to the alexandrite artificial corundum crystal, as described in the column “A. Artificial corundum crystal”; therefore, as the raw material, there can be used at least one kind of compound selected from an iron compound, a titanium compound and a chromium compound, together with an aluminum compound and a vanadium compound.

In this case, examples of the combination of components of the raw material include the following combinations: an aluminum compound and a vanadium compound; an aluminum compound, a vanadium compound, and an iron compound; an aluminum compound, a vanadium compound, and a titanium compound; an aluminum compound, a vanadium compound, and a chromium compound; an aluminum compound, a vanadium compound, an iron compound, and a titanium compound; an aluminum compound, a vanadium compound, an iron compound, and a chromium compound; an aluminum compound, a vanadium compound, a titanium compound, and a chromium compound; and an aluminum compound, a vanadium compound, an iron compound, a titanium compound, and a chromium compound.

The vanadium compound is not particularly limited if the compound is a compound which is melted in the heating/vaporizing step, which will be described later. The compound is preferably a compound which is heated to generate a vanadium ion. Examples of the compound, which is heated to generate a vanadium ion, include a vanadium carbide, a vanadium chloride, a vanadium oxide, a vanadium oxysulfate, a vanadium oxalateoxidehydrate, and hydrates thereof. Of these, the vanadium oxide is preferably used in the invention. In this case, the valence of the vanadium in the vanadium oxide includes trivalence, quadrivalence and quinquevalence. About the valence of vanadium, a single valence or mixed valences therefrom are permissible.

The aluminum compound is the same as described in the column of the colorless artificial corundum crystal. The chromium compound is the same as described in the column of the dark red, red or pink artificial corundum crystal. The iron compound and the titanium compound are the same as described in the column of the blue artificial corundum crystal. Thus, description thereof is not repeated herein.

The mixing ratio between the aluminum compound and the vanadium compound is not particularly limited if the vanadium compound is added in an amount which makes it possible to color the crystal into the alexandrite artificial corundum crystal. In the case of using at least one kind of compound selected from an iron compound, a titanium compound, and a chromium compound together with the aluminum compound and the vanadium compound, the mixing ratio is not also particularly limited if the vanadium compound and other compounds which become coloring components are added in an amount making it possible to color the crystal into the alexandrite artificial corundum crystal.

In the case of using, for example, an aluminum oxide and a vanadium oxide as the raw material, the adding amount of the vanadium oxide should be 5% or less by weight of the aluminum oxide weight; is preferably 2% or less by weight thereof; and is more preferably 1% or less by weight thereof. By setting the mixing ratio into the above-mentioned range, the alexandrite artificial corundum crystal is colored into alexandrite color good in color-changeability.

In the case of using, for example, an aluminum oxide, a vanadium oxide and an iron oxide as the raw material, the total adding amount of the vanadium oxide and the iron oxide should be 5% or less by weight of the aluminum oxide weight; is preferably 2% or less by weight thereof; and is more preferably 1% or less by weight thereof. By setting the mixing ratio into the above-mentioned range, the alexandrite artificial corundum crystal is colored into alexandrite color good in color-changeability, as described above. In such a case, the mixing ratio between the vanadium oxide and the iron oxide is varied by the valences of a vanadium and an iron, and should be appropriately selected in accordance with the usage of the alexandrite artificial corundum crystal produced by the invention.

As described above, in the invention, an iron compound, a titanium compound or a chromium compound can be variably combined with the above-mentioned aluminum compound and vanadium compound, and the combination can be used. The mixing ratio between these compounds is varied by the valence of each of the elements therein, and is appropriately selected in accordance with the usage of the alexandrite artificial corundum crystal produced by the invention.

The content of the raw material is the same as described in the column of the colorless artificial corundum crystal, and the composition of the alexandrite artificial corundum crystal is the same as described in the column of “A. Artificial corundum crystal”. Thus, description thereof is not repeated herein.

(vi) Green Artificial Corundum Crystal

Since the green artificial corundum crystal has a basic composition represented by, for example, Al₂O₃:Co in the invention, an aluminum compound and a cobalt compound can be used as the raw material. An iron, a vanadium, a nickel, or the like as a coloring component may be added, together with a cobalt, to the green artificial corundum crystal, as described in the column “A. Artificial corundum crystal”; therefore, as the raw material, there can be used at least one kind of compound selected from an iron compound, a vanadium compound and a nickel compound together with an aluminum compound and a cobalt compound.

In this case, examples of the combination of components of the raw material include the following combinations: an aluminum compound and a cobalt compound; an aluminum compound, a cobalt compound, and an iron compound; an aluminum compound, a cobalt compound, and a vanadium compound; an aluminum compound, a cobalt compound, and a nickel compound; an aluminum compound, a cobalt compound, a vanadium compound, and a nickel compound.

The cobalt compound is not particularly limited if the compound is a compound that is melted in the heating/vaporizing step, which will be described later. The compound is preferably a compound which is heated to generate a cobalt ion. Examples of the compound, which is heated to generate a cobalt ion, include a cobalt bromide, a cobalt chloride, a cobalt citrate, a cobalt fluoride, a cobalt gluconate, a cobalt hydroxide, a cobalt iodide, a cobalt nitrate, a cobalt oxalate, a cobalt oxide, a cobalt phosphate, a cobalt stearate, a cobalt sulfate, a cobalt sulfide, and hydrates thereof. Of these, the following are preferably used in the invention: the cobalt citrate, the cobalt fluoride, the cobalt gluconate, the cobalt hydroxide, the cobalt iodide, the cobalt oxalate, the cobalt oxide, the cobalt phosphate, and the cobalt stearate. It is particularly preferred to use the cobalt oxide, the cobalt hydroxide, the cobalt stearate and the cobalt phosphate. In this case, the valence of cobalt in the cobalt compound may be bivalent or trivalent. A bivalent cobalt and a trivalent cobalt may be mixed.

The aluminum compound is the same as described in the column of the colorless artificial corundum crystal. The iron compound is the same as described in the column of the blue artificial corundum crystal. The nickel compound is the same as described in the column of the yellow artificial corundum crystal. The vanadium compound is the same as described in the column of the alexandrite artificial corundum crystal. Thus, description thereof is not repeated herein.

The mixing ratio between the aluminum compound and the cobalt compound is not particularly limited if the cobalt compound is added in an amount which makes it possible to color the crystal into the green artificial corundum crystal. In the case of using at least one kind of compound selected from an iron compound, a vanadium compound, and a nickel compound together with the aluminum compound and the cobalt compound, the mixing ratio is not also particularly limited if the cobalt compound and other compounds which become coloring components are added in an amount making it possible to color the crystal into the green artificial corundum crystal.

In the case of using, for example, the aluminum oxide and the cobalt oxide as the raw material, the adding amount of the cobalt oxide should be 5% or less by weight of the aluminum oxide weight; is preferably 2% or less by weight thereof; and more preferably 1% or less by weight thereof. By setting the mixing ratio into the above-mentioned range, the green artificial corundum crystal is colored into vivid green color.

In the case of using, for example, the aluminum oxide, the cobalt oxide and the iron oxide as the raw material, the total adding amount of the cobalt oxide and the iron oxide should be 5% or less by weight of the aluminum oxide weight; is preferably 2% or less by weight thereof; and more preferably 1% or less by weight thereof. By setting the mixing ratio into the above-mentioned range, the green artificial corundum crystal is colored into vivid green color, as described above. In such a case, the mixing ratio between the cobalt oxide and the iron oxide is varied by the valences of a cobalt and an iron, and should be appropriately selected in accordance with the usage of the green artificial corundum crystal produced by the invention.

As described above, in the invention, an iron compound, a vanadium compound or a nickel compound can be variably combined with the above-mentioned aluminum compound and cobalt compound, and the combination can be used. The mixing ratio between these compounds is varied by the valence of each of the elements therein, and is appropriately selected in accordance with the usage of the green artificial corundum crystal produced by the invention.

The content of the raw material is the same as described in the column of the colorless artificial corundum crystal, and the composition of the green artificial corundum crystal is the same as described in the column of “A. Artificial corundum crystal”. Thus, description thereof is not repeated herein.

(3) Others

In the invention, an impurity may be contained into the above-mentioned sample. This makes it possible to produce a crystal near natural crystal and yield an artificial corundum crystal high in value as an ornament or the like.

2. Heating/Vaporizing Step

The following describes the heating/vaporizing step in the process for producing an artificial corundum crystal of the invention. The heating/vaporizing step in the invention is a step of heating the sample containing the flux and the raw material and further keeping the sample at high temperature to vaporize the flux.

In the present step, the sample prepared in the sample-preparing step is filled into a crucible, and then the crucible is covered with a lid. As shown in, for example, FIG. 5B, a crucible 12 into which a sample 1 is filled is set in a high-temperature furnace 13. Next, the temperature thereof is raised to a maximum keeping temperature, and the sample is kept at the temperature for a given time, thereby vaporizing the flux in the sample 1 and promoting nuclei formation and crystal growth by use of the evaporation of the flux as a driving force. In this way, an artificial corundum crystal 2 is produced in the sample 1.

The maximum keeping temperature in the step is not particularly limited if the temperature is a temperature at which the sample is melted and the flux is vaporized. Specifically, the temperature is preferably from 950 to 1300° C.; more preferably from 975 to 1250° C.; and in particular preferably from 1000 to 1200° C.

The temperature-raising rate when the maximum keeping temperature is set is not particularly limited if the rate is a rate making it possible to heat the sample uniformly. Furthermore, the time for keeping the sample at the maximum keeping temperature is not particularly limited if the time is a time making it possible to grow the crystal sufficiently.

The crucible used in the step is not particularly limited if the crucible is a crucible which can resist the maximum keeping temperature and is low in reactivity with the sample. Usually, a platinum crucible is used.

3. Cooling Step

The following describes the cooling step in the process for producing an artificial corundum crystal of the invention. The cooling step in the invention is a step of cooling the sample melted in the heating/vaporizing step.

In the step, the crucible 12 filled with the sample 1 is taken out from the high-temperature furnace 13 as shown in, for example, FIG. 5B, and then the crucible 12 filled with the sample 1 is cooled to a room temperature, as shown in FIG. 5C.

The method for the cooling may be any method that makes it possible to cool the sample to a room temperature, and is a method of cooling the crucible naturally, or the like.

4. Separating Step (Crystal-Collecting Step)

The following describes the separating step in the process for producing an artificial corundum crystal of the invention. The separating step in the invention is a step of dissolving the sample remaining after the heating/vaporizing step and the cooling step into an appropriate medium, thereby separating the crystal.

After the cooling step, a sample 1′ in which the artificial corundum crystal 2 is taken in remains the crucible, as shown in FIG. 5C. In the step, this remaining sample is dissolved into an appropriate medium, whereby only the artificial corundum crystal can easily be separated.

The medium used to dissolve the remaining sample is not particularly limited if the medium is a medium in which the remaining sample other than the artificial corundum crystal can be dissolved without affecting the artificial corundum crystal. Examples thereof include cool water, warm water, and hot water.

Other matters of the artificial corundum crystal produced by the invention are the same as described in the column “A. Artificial corundum crystal”. Thus, description thereof is not repeated herein.

C. A Raw Material for Producing an Artificial Corundum Crystal

The following describes a raw material for producing an artificial corundum crystal.

A raw material for producing an artificial corundum crystal of the invention is used to produce an artificial corundum crystal, and is characterized by containing a molybdenum compound and an aluminum compound.

A raw material for producing an artificial corundum crystal of the invention is a material which is preferably used when an artificial corundum crystal is produced by the above-mentioned flux evaporation method. When the raw material for producing an artificial corundum crystal of the invention is used to produce an artificial corundum crystal, it is possible not to produce a tabular crystal or needle crystal but to produce a hexagonally dipyramidal crystal selectively. Accordingly, the crystal can be put into practical use at low costs. Moreover, the invention has an advantage that a crystal high in value as an ornament or the like can be obtained.

A raw material for producing an artificial corundum crystal of the invention may contain a chromium compound, iron and titanium compounds, a nickel compound, a vanadium compound, or a cobalt compound in addition to the above-mentioned molybdenum compound and aluminum compound. When the raw material for producing an artificial corundum crystal contains such a compound, the material can be preferably used to produce an artificial corundum crystal colored into any one of various colors.

For example, the raw material for producing an artificial corundum crystal used to produce a yellow artificial corundum crystal may contain an iron compound in addition to the above-mentioned molybdenum compound, aluminum compound and nickel compound.

A raw material for producing an artificial corundum crystal used to produce an alexandrite artificial corundum crystal may contain at least one kind of compound selected from an iron compound, a titanium compound, and a chromium compound in addition to the above-mentioned molybdenum compound, aluminum compound and vanadium compound. Examples of the combination of these compounds may the combinations described in the column “B. A process for producing an artificial corundum crystal, 1. Sample-preparing step”.

A raw material for producing an artificial corundum crystal used to produce a green artificial corundum crystal may contain at least one kind of compound selected from an iron compound, a vanadium compound and a nickel compound in addition to the above-mentioned molybdenum compound, aluminum compound and cobalt compound. Examples of the combination of these compounds may the combinations described in the column “B. A process for producing an artificial corundum crystal, 1. Sample-preparing step”.

Furthermore, the raw material for producing an artificial corundum crystal of the invention may contain an alkali metal compound. The alkali metal compound inhibits the molybdenum compound or the like from evaporating; therefore, when the raw material for producing an artificial corundum crystal of the invention is used to produce an artificial corundum crystal, the formation of polynuclei and the speed of crystal growth can be suppressed so that a high-quality artificial corundum crystal can be obtained.

The molybdenum compound, the aluminum compound, the chromium compound, the iron compound, the titanium compound, the nickel compound, the vanadium compound, the cobalt compound and the alkali metal compound, the contents of these compounds, and others are the same as described in the column “B. A process for producing an artificial corundum crystal, 1. Sample-preparing step”. Thus, description thereof is not repeated herein.

The invention is not limited to the above-mentioned embodiments. The embodiments are illustrative, and any embodiment which has a construction which is substantially equivalent to the technical conception recited in the claims of the invention and produces similar effects is included in the technical scope of the invention.

### EXAMPLES

The invention will be specifically described by way of working examples and comparative examples hereinafter.

### Example 1

First, an aluminum oxide (1.5 g), a chromium oxide (0.008 g), a molybdenum oxide (28.5 g), and a lithium carbonate (1.5 g) were weighed, and then put into a mortar. This blended sample was dry-mixed in the mortar for about 20 minutes. Thereafter, the blended sample was filled into a platinum crucible, and the crucible was covered with a lid to be set into an electric furnace. The electric furnace was heated to 1100° C. at a rate of 45° C. per hour, and kept at the temperature for 5 hours. After the furnace was kept, the crucible was taken out from the electric furnace, and naturally cooled to the room temperature. The crucible cooled to the room temperature was put into warm water so as to separate/collect a chromium-added artificial corundum crystal. The resultant crystal had a three-dimensional shape having a hexagonally dipyramidal shape as its basic shape, and was transparent and dark red. The average size thereof was about 1 mm in each of “a” axis and “c” axis directions.

### Comparative Example 1

First, an aluminum oxide (5.2 g), a chromium oxide (0.05 g), and a lead fluoride (49.8 g) were weighed, and then put into a mortar. This blended sample was dry-mixed in the mortar for about 20 minutes. Thereafter, the blended sample was filled into a platinum crucible, and the crucible was covered with a lid to be set into an electric furnace. The electric furnace was heated to 1100° C. at a rate of 45° C. per hour, and kept at the temperature for 10 hours. After the furnace was kept, the crucible was slowly cooled to 600° C. at a rate of 5° C. per hour. The crucible was taken out from the electric furnace, and naturally cooled to the room temperature. The crucible cooled to the room temperature was put into warm water so as to separate/collect a chromium-added artificial corundum crystal. The resultant crystal was a transparent red crystal having a tabular shape as its basis shape.

### Example 2

An aluminum oxide (1.5 g), a titanium oxide (0.002 g), an iron oxide (0.002 g), a molybdenum oxide (28.5 g), and a lithium carbonate (1.5 g) were weighed, and then put into a mortar. This blended sample was dry-mixed in the mortar for about 20 minutes. Thereafter, the blended sample was filled into a platinum crucible, and the crucible was covered with a lid to be set into an electric furnace. The electric furnace was heated to 1100° C. at a rate of 45° C. per hour, and kept at the temperature for 5 hours. After the furnace was kept, the crucible was taken out from the electric furnace, and naturally cooled to the room temperature. The crucible cooled to the room temperature was put into warm water so as to separate/collect a blue artificial corundum crystal. The resultant crystal had a three-dimensional shape having a hexagonally dipyramidal shape as its basic shape, and was transparent and blue.

### Comparative Example 2

An aluminum oxide (5.2 g), a titanium oxide (0.0125 g), an iron oxide (0.0125 g), and a lead fluoride (49.8 g) were weighed, and then put into a mortar. This blended sample was dry-mixed in the mortar for about 20 minutes. Thereafter, the blended sample was filled into a platinum crucible, and the crucible was covered with a lid to be set into an electric furnace. The electric furnace was heated to 1100° C. at a rate of 45° C. per hour, and kept at the temperature for 10 hours. After the furnace was kept, the crucible was slowly cooled to 600° C. at a rate of 5° C. per hour. The crucible was taken out from the electric furnace, and naturally cooled to the room temperature. The crucible cooled to the room temperature was put into warm water so as to separate/collect an artificial corundum crystal. The resultant crystal was a transparent blue crystal having a tabular shape as its basis shape.

### Example 3

An aluminum oxide (1.5 g), a nickel oxide (0.008 g), a molybdenum oxide (28.5 g), and a lithium carbonate (1.5 g) were weighed, and then put into a mortar. This blended sample was dry-mixed in the mortar for about 20 minutes. Thereafter, the blended sample was filled into a platinum crucible, and the crucible was covered with a lid to be set into an electric furnace. The electric furnace was heated to 1100° C. at a rate of 45° C. per hour, and kept at the temperature for 5 hours. After the furnace was kept, the crucible was taken out from the electric furnace, and naturally cooled to the room temperature. The crucible cooled to the room temperature was put into warm water so as to separate/collect a yellow artificial corundum crystal. The resultant crystal had a three-dimensional shape having a hexagonally dipyramidal shape as its basic shape, and was transparent and yellow.

### Example 4

An aluminum oxide (1.5 g), a vanadium oxide (0.008 g), a molybdenum oxide (28.5 g), and a lithium carbonate (1.5 g) were weighed, and then put into a mortar. This blended sample was dry-mixed in the mortar for about 20 minutes. Thereafter, the blended sample was filled into a platinum crucible, and the crucible was covered with a lid to be set into an electric furnace. The electric furnace was heated to 1100° C. at a rate of 45° C. per hour, and kept at the temperature for 5 hours. After the furnace was kept, the crucible was taken out from the electric furnace, and naturally cooled to the room temperature. The crucible cooled to the room temperature was put into warm water so as to separate/collect an alexandrite artificial corundum crystal. The resultant crystal had a three-dimensional shape having a hexagonally dipyramidal shape as its basic shape, and exhibited transparent alexandrite color.

### Example 5

An aluminum oxide (1.5 g), a cobalt oxide (0.008 g), a molybdenum oxide (28.5 g), and a lithium carbonate (1.5 g) were weighed, and then put into a mortar. This blended sample was dry-mixed in the mortar for about 20 minutes. Thereafter, the blended sample was filled into a platinum crucible, and the crucible was covered with a lid and set into an electric furnace. The electric furnace was heated to 1100° C. at a rate of 45° C. per hour, and kept at the temperature for 5 hours. After the furnace was kept, the crucible was taken out from the electric furnace, and naturally cooled to the room temperature. The crucible cooled to the room temperature was put into warm water so as to separate/collect a green artificial corundum crystal. The resultant crystal had a three-dimensional shape having a hexagonally dipyramidal shape as its basic shape, and was transparent and green.

### INDUSTRIAL APPLICABILITY

The artificial corundum crystal of the invention can be put into practical use at low costs, and is also high in value as an ornament or the like.

1. A process for producing an artificial corundum crystal,
wherein an artificial corundum crystal having a hexagonally dipyramidal shape as its base shape is produced by a flux evaporation method of heating a sample containing a raw material and a flux to precipitate a crystal and grow the crystal by use of a flux evaporation as a driving force,
wherein the flux contains an evaporation inhibitor,
wherein the evaporation inhibitor is an alkali metal compound, and
wherein the alkali metal compound is a compound which is heated to generate at least one kind of alkali metal oxide selected from a group consisting of Li₂O, Na₂O, and K₂O.

2. The process for producing an artificial corundum crystal according to claim 1, wherein the flux contains a molybdenum compound.

3. The process for producing an artificial corundum crystal according to claim 2,
wherein the molybdenum compound is a molybdenum oxide or a compound which is heated to generate the molybdenum oxide.

4. The process for producing an artificial corundum crystal according to claim 1, wherein a mol number of an alkali metal atom in the alkali metal compound is 40% or less by mol of total mol numbers of the sample.

5. The process for producing an artificial corundum crystal according to claim 1, wherein a mol number of the raw material is 10% or less by mol of total mol numbers of the sample.
